(19) United States
(12) Patent Application Publication
(10) Pub. No.: US 2016/0111905 A1
(43) Pub. Date: Apr. 21, 2016

(54) SYSTEMS AND METHODS FOR CHARGING ENERGY STORAGE DEVICES

(71) Applicant: Elwha LLC, Bellevue, WA (US)

(72) Inventors: William D. Duncan, Mill Creek, WA (US); Jordin T. Kare, Seattle, WA (US); Thomas A. Weaver, San Mateo, CA (US); Lowell L. Wood, JR., Bellevue, WA (US)

(73) Assignee: ELWHA LLC, Bellevue, WA (US)

(21) Appl. No.: 14/517,388

(22) Filed: Oct. 17, 2014

(51) Int. Cl. H02J 7/00; G01R 31/36

(52) U.S. Cl. CPC H02J 7/0052; G01R 31/3648; G01R 31/3634; G01R 31/3658

(57) ABSTRACT

An electronic device for use in charging a battery includes a housing, a display device coupled to the housing, and a control circuit disposed within the housing. The control circuit is configured to determine a plurality of different options for charging a battery, including determining a predicted impact on the overall life of the battery for each of the plurality of options, display the plurality of options for charging the battery on the display device, each of the plurality of options including an indication of the predicted impact on the overall life of the battery, receive a user input identifying a user selection of one of the plurality of options, and charge the battery in accordance with the selected option.

### BACKGROUND

Various types of electronic systems and devices, such as cellular phones, laptop computers, electric vehicles, and the like, often utilize one or more rechargeable energy storage devices such as rechargeable batteries as a source of power. The rate at which a battery or other energy storage device is recharged can be varied from relatively short charge periods, such as a few minutes, to relatively long charge periods, such as several hours. Varying the length of the charge period can impact various operational characteristics of the battery or storage device, including the capacity and the overall cycle life.

### SUMMARY

One embodiment relates an electronic device for use in charging an energy storage device, including a user interface device; and a control circuit coupled to the user interface device and configured to determine a plurality of different options for charging an energy storage device, including determining a predicted impact on the overall life of the energy storage device for each of the plurality of options; provide the plurality of options for charging the energy storage device to the user interface device, each of the plurality of options including an indication of the predicted impact on the overall life of the energy storage device; receive a user input identifying a user selection of one of the plurality of options; and charge the energy storage device in accordance with the selected option.

Another embodiment relates an electronic device configured to charge an energy storage device, including an output device; and a control circuit coupled to the output device, the control circuit configured to determine a plurality of options for charging an energy storage device, including determining a predicted impact on the overall life of the energy storage device for each of the plurality of options; provide the plurality of options to a user via the output device; and charge the energy storage device in accordance with one of the plurality of options.

Another embodiment relates to a method of charging a battery, including determining a plurality of options for charging the battery; predicting an impact on the overall life of the battery for each of the plurality of options; providing the plurality of options for charging the battery to a user, each of the plurality of options including an indication of the predicted impact on the overall life of the battery; receiving an input identifying one of the plurality of options; and charging the battery in accordance with the selected option.

Another embodiment relates to a method of charging an energy storage device, including determining a predicted impact on an overall life of an energy storage device for a charging option; charging the energy storage device in accordance with the charging option; receiving charging data regarding one or more characteristics of the energy storage device related to charging the energy storage device; determining an updated impact on the overall life of the energy storage device based on the charging data; and providing the updated impact to a user.

Another embodiment relates to a method of charging an energy storage device, including receiving a user input identifying a charge option for an energy storage device; determining a plurality of charging parameters for a charge cycle based on the input; monitoring charging characteristics of the energy storage device during the charge cycle; and dynamically modifying one or more of the charging parameters during the charge cycle based on monitoring of the charging characteristics.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a front view of a charger according to one embodiment.

FIG. 2 is a schematic block diagram of the charger of FIG. 1 according to one embodiment.

FIG. 3 is a cross-section view of an energy storage device according to one embodiment.

FIG. 4A is a line graph illustrating charge and discharge cycles for an energy storage device according to one embodiment.

FIG. 4B is an illustration of various battery capacities for different charge rates according to one embodiment.

FIG. 5 is a front view of a display of various charging options according to one embodiment.

FIG. 6 is a front view of a display of various charging options according to another embodiment.

FIG. 7 is a front view of a display of various charging parameters for a charge cycle according to one embodiment.

FIG. 8 is a front view of a display of updated storage device data according to one embodiment.

FIG. 9 is a schematic block diagram of a charging system according to an alternative embodiment.

FIG. 10A is a schematic illustration of a charging system according to another alternative embodiment.

FIG. 10B is a schematic illustration of a charging system implemented in a vehicle according to another embodiment.

FIG. 11 is a block diagram of a method of charging an energy storage device according to one embodiment.

FIG. 12 is a block diagram of a method of charging an energy storage device according to another embodiment.

FIG. 13 is a schematic illustration of a multi-cell battery pack according to one embodiment.

### DETAILED DESCRIPTION

In the following detailed description, reference is made to the accompanying drawings, which form a part thereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

Referring to the figures generally, the present disclosure relates generally to intelligently charging energy storage devices such as rechargeable batteries. For example, rechargeable batteries can lose their charge as a result of use, passage of time, or other factors. As such, the batteries are periodically recharged. Batteries may be recharged using a “slow charge” or a “fast charge.” In a slow charge, the battery is charged over a relatively longer time period (e.g., hours) such that the battery does not experience any substantial damage due to excessive voltage, current, temperature, or the like. For example, using a slow charge, a typical twelve volt vehicle battery may be charged at a two amp charge rate in approximately eight to ten hours. In a fast charge, the battery is charged in a relatively shorter time period (e.g., minutes), typically using higher voltage, current, or temperature, which can result in damage to the battery, including shortening the overall life (e.g., the total number of times the battery can be charged) of the battery. For example, a typical twelve volt battery may be charged at a six or ten amp charge rate in approximately two hours. Batteries for smaller electronic devices can often be fast-charged in minutes, rather than hours.

Other energy storage devices (e.g., a fuel cell or flow-type battery, etc.) in general may have charge-discharge characteristics and overall life cycles very different from rechargeable electrochemical batteries, but many do have short- and long-term characteristics that depend at least partially on how they are charged. As an example, the separator membranes in a fuel-cell or flow-type battery may be incrementally degraded by high recharge rates, or alternatively, may have a higher risk of abrupt failure at high currents. Using a “fast charge” may reduce the number of cycles before you have to remove the separator, or alternatively, increase the chance of failure by a certain percentage (e.g., 5%, 10%, etc.).

Under certain circumstances, a user may need or desire a fast charge for an energy storage device. This may be the case, for example, should a user be at an airport, and want to charge a battery of a cellular phone, laptop, or similar device during a limited time period between flights. As such, the user may be willing to quickly charge the battery even knowing that this may impact the overall life of the battery. However, the predicted impact of a fast charge is often unknown to the user. As such, various embodiments disclosed herein relate to providing users options and information regarding recharging a battery or other device such that the user can make an informed decision based on the user's charging needs and the resulting impact of a selected charging option on the overall life of the battery. For example, different charging options may involve different charge times, different charge voltages or currents, different charge temperatures for the battery, and so on. For each option, the user may be provided with the predicted impact of the charging option on the overall life of the battery, such that the user can make an informed, intelligent decision as to whether the convenience of a fast charge is worth the cost in battery life.

It should be noted that while in some embodiments an energy storage device may be referred to herein as a battery, the teachings herein may extend equally to other energy storage devices such as capacitors (e.g., ultracapacitors), flywheel energy storage systems (e.g., micro-flywheels, etc.), fuel cell systems, and the like. As such, rather than a predicted impact on life cycle, the predicted impact may relate to efficiency (e.g., heat generation during charging and discharging), probability of sudden degradation or failure, or other type of charge-rate-dependent characteristic.

Referring now to FIG. 1, charger 10 (e.g., a battery charger, etc.) is shown according to one embodiment. Charger 10 includes housing 12, display device 14, and one or more input or output devices shown as buttons 16 and microphone/speaker device 18. Charger 10 further includes port 20 (e.g., a battery port, etc.), connection port 22, charging cord 24, and power cord 26. According to various alternative embodiments, charger 10 can include more or fewer components than those shown in FIG. 1, and various components can be combined into integrated components or subdivided into sub-components.

Charger 10 is configured to recharge one or more energy storage devices 32 (e.g., rechargeable batteries, capacitors, flywheel systems, etc.). For example, host device 30 (e.g., an electronic device, cellular phone, laptop computer, vehicle, etc.) may utilize storage device 32 as a power source in the form of a rechargeable battery. Charger 10 and device 30 can be configured such that storage device 32 can be recharged by way of charging cord 24 or a similar connection between charger 10 and device 30. Alternatively, one or more storage devices 32 can be placed directly into ports 20 disposed in housing 12 of charger 10. Charger 10 can receive power from a conventional wall outlet or other power source (e.g., via power cord 26 and plug 28) and provide the appropriate charging voltage and current to storage device 32, either via port 20 or via charging cord 24. As discussed in greater detail below, in some embodiments, some or all of the components and features of charger 10 can be integrated into an electronic device such as host device 30 to avoid the need for a separate charging device.

Charger 10 can take any suitable form or shape, and be provided as a mobile charger or a stationary charging station integrated into a larger structure. Display 14 (e.g., a user interface, input/output device, etc.) is configured to provide various outputs to a user, and in some embodiments can be configured to receive inputs from a user. For example, display 14 can include touch-sensitive features (e.g., a touch screen) such that display 14 can receive tactile inputs from a user. Buttons 16 can provide additional input capabilities for users, and buttons 16 can include any number of buttons that may have preprogrammed functions (e.g., on/off, etc.). Audio input and output device 18 can provide audio input and output features and can include a microphone, speaker, or similar device to enable receipt of voice commands from a user, enable audible outputs to be provided to a user, and so on.

Port 20 is configured to receive one or more energy storage devices such as rechargeable batteries. As shown in FIG. 1, port 20 can be integrated into housing 12 of charger 10. In other embodiments, port 20 may further include terminal leads that enable a user to connect charger 10 to a battery without having to physically place the battery into port 20. Port 20 can be sized to fit a specific battery type or size. According to various alternative embodiments, port 20 can be configured to accommodate different sizes and types of energy storage devices such as batteries. As such, charger 10 can charge energy storage devices in a variety of different situations, including while a battery is installed in a host device (e.g., device 30), while a battery is removed from a host device, and while a battery is disposed within a battery port such as port 20. The various teachings herein extend to all such embodiments.

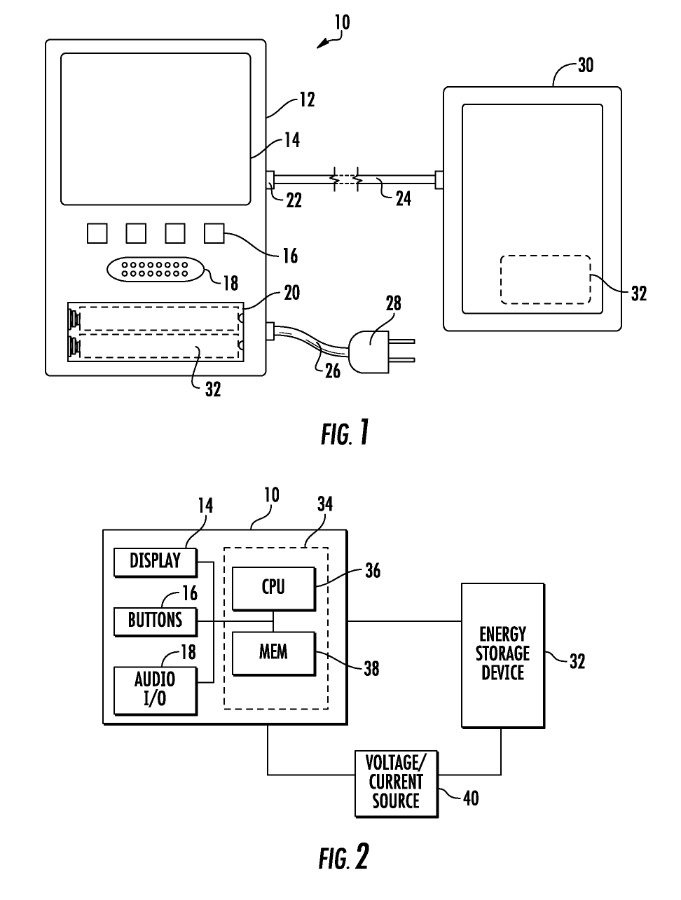

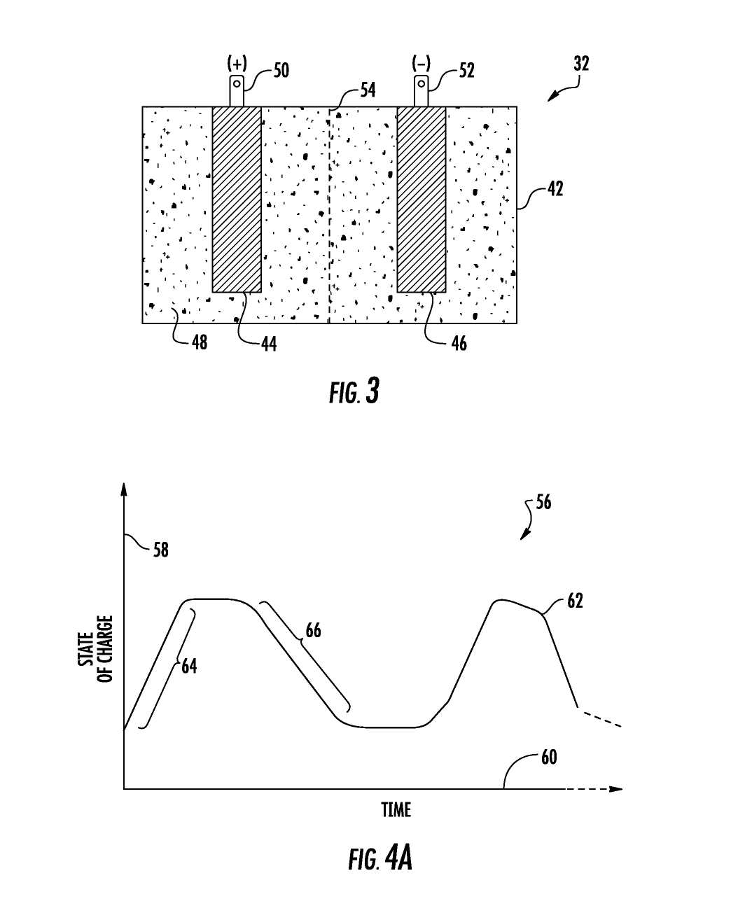

Referring to FIG. 2, processing circuit 34 usable with charger 10 is shown according to one embodiment. Circuit 34 includes processor 36 and memory 38. Circuit 34 is configured to communicate with various input and output devices, including display 14, buttons 16, and audio input/output device 18, to receive various inputs from, and provide various outputs to, a user. For example, as discussed in greater detail below, circuit 34 can provide various charging options for charging storage device 32 to a user via display 14. A user can select a desired charging option from the displayed options by, for example, touching display 14 (in the case of a touchscreen display) or pressing one of buttons 16. Based on the user selection, circuit 34 can then control operation of charging source 40 (e.g., a voltage and current source) to charge storage device 32 in accordance with the selected option.

Processor 36 may be implemented as a general-purpose processor, an application specific integrated circuit (ASIC), one or more field programmable gate arrays (FPGAs), a digital-signal-processor (DSP), a group of processing components, or other suitable electronic processing components. Memory 38 is one or more devices (e.g., RAM, ROM, Flash Memory, hard disk storage, etc.) for storing data and/or computer code for facilitating the various processes described herein. Memory 38 may be or include non-transient volatile memory or non-volatile memory. Memory 38 may include database components, object code components, script components, or any other type of information structure for supporting the various activities and information structures described herein. Memory 38 may be communicably connected to processor 36 and provide computer code or instructions to processor 36 for executing the processes described herein.

Referring now to FIG. 3, storage device 32 is shown in the form of a battery according to one embodiment. It should be understood that the details of storage device 32 are provided for illustration purposes, and as such, the components of storage device 32 may differ from those shown in FIG. 3, and the particular configuration of FIG. 3 should not be viewed as limiting. As shown in FIG. 3, storage device 32 includes a housing 42 within which various components (e.g., active components) are contained, including positive electrode 44, negative electrode 46, and electrolyte 48. A separator such as separator 54 may be utilized to separate the electrolyte surrounding the positive electrode and the electrolyte surrounding the negative electrode. Positive electrode 44 is coupled to positive terminal 50, and negative electrode 46 is coupled to negative terminal 52. Terminals 50, 52 are configured to be electrically coupled to exterior devices, such as a host device or battery charger.

According to one embodiment, storage device 32 includes one or more electrochemical cells that convert chemical energy to electrical energy. During charge and discharge, positively and negatively charged ions move through electrolyte 48 between the positive and negative electrodes 44, 46. The direction of travel of the ions is reversed between charging and discharging cycles.

In various alternative embodiments, storage device 32 can include a wide variety of battery types, and take various shapes and sizes. For example, storage device 32 can be a lead acid, lithium ion, nickel cadmium, lithium ion polymer, or other type of battery. Furthermore, storage device 32 can be usable in a wide variety of applications and with a range of host devices, such as cellular phones, laptop or portable computers, vehicles that utilize one or more batteries, and other portable consumer devices. In some embodiments, storage device 32 can include a multi-cell battery pack, such as battery pack 33 shown in FIG. 13. As shown in FIG. 13, multiple cells 35 are coupled to form battery pack 33. Cells 35 can be coupled in series, parallel, or using a combination of series and parallel connections. For example, for smaller-sized batteries, cells 35 are typically connected in series, as shown in FIG. 13. In some embodiments, charge 10 is configured to access one or more nodes 37 (e.g., to interrupt a series or parallel connection) in order to charge and/or obtain test data regarding various isolated cells or groups of cells within a battery pack. As such, determinations regarding battery pack life, required maintenance, and the like, may be at least partially based on measurements of less than all of the individual cells within battery packs.

Storage device 32 is recharged by applying current to the storage device via terminals 50, 52. A given storage device such as a battery will have a battery life that can be defined in terms of the total number of times the battery can be recharged (e.g., using slow charge recharging cycles). As such, if, during a (slow) charge cycle, voltage, current, and temperature are maintained within certain levels (which may be battery-specific), substantial damage to the battery is typically avoided, such that the life of the battery is reduced by approximately one charge cycle. However, if a fast charge cycle is utilized, such that the voltage, current, or temperature exceed certain levels, the reduction of the life of the battery life may be accelerated (e.g., such that a fast charge cycle may reduce the overall battery life by more than one charge cycle).

It should be understood that while FIGS. 1-3 provide illustrative embodiments of energy storage devices in the form of a battery or battery pack, according to various other embodiments, the energy storage device may take other forms, such as a capacitor (e.g., an ultracapacitor), a flywheel assembly (e.g., a micro-flywheel), rechargeable fuel cell, or any other energy storage device where charging factors may impact and/or be dynamically changed to achieve desired charging characteristics for the energy storage device.

While in some embodiments, overall life of the energy storage device can be expressed in terms of charge cycles remaining, in other embodiments, storage device life can be expressed in terms of time (e.g., hours, days, months, etc.), or in other ways. For example, based on the usage history of the storage device, the future frequency of charge cycles can be predicted such that based on the expected charge cycles remaining, a storage device life expectancy can be predicted. In yet further embodiments, storage device life can be expressed in terms of the amount of time until service is required (e.g., in the case of lithium batteries that may require periodic charge balancing, etc.).

As part of the charging process, it is often helpful to ascertain certain characteristics of the storage device, including a current state of charge (SOC) for the storage device, along with the storage device's tolerance of various fast charge scenarios (e.g., to determine the impact of various fast charge cycles on the overall life of the storage device). SOC and storage device life impact can be determined in a variety of ways, and can be based on a variety of different factors.

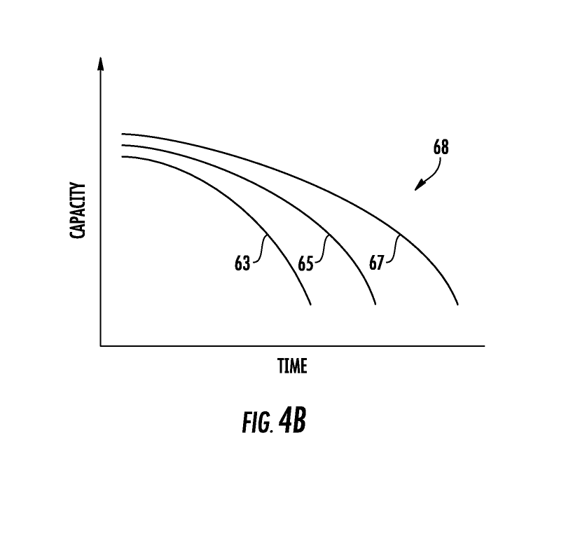

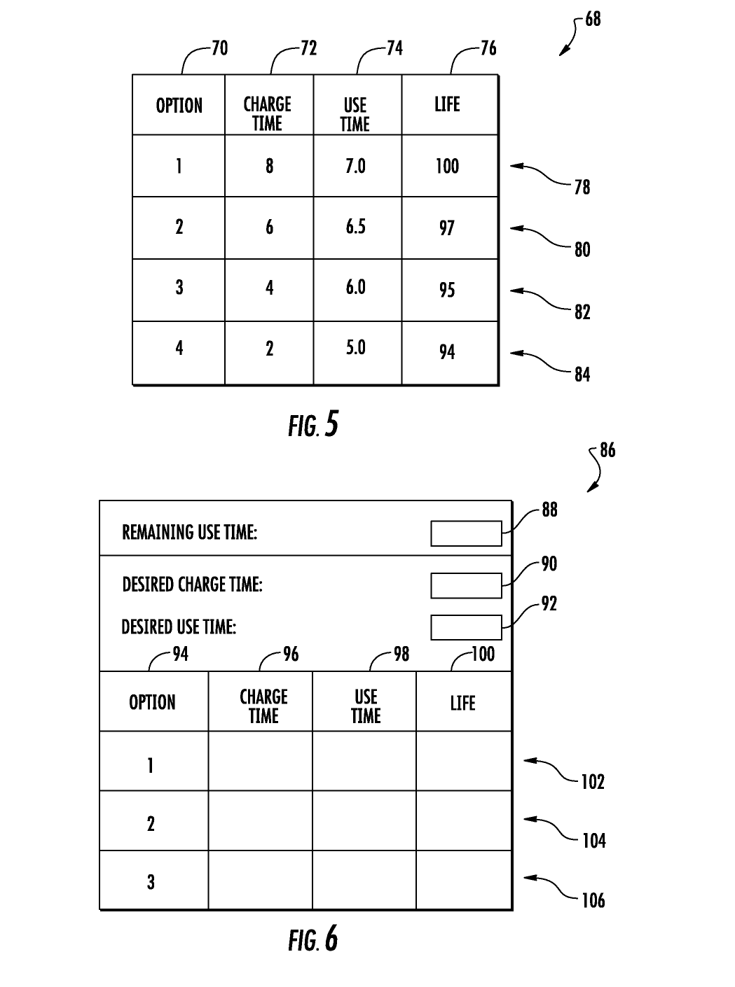

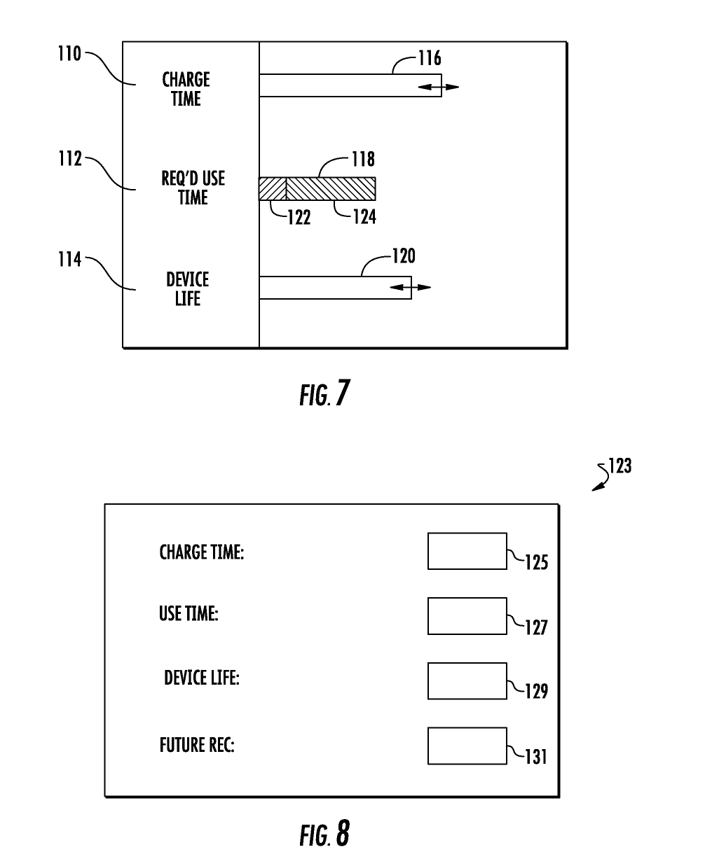

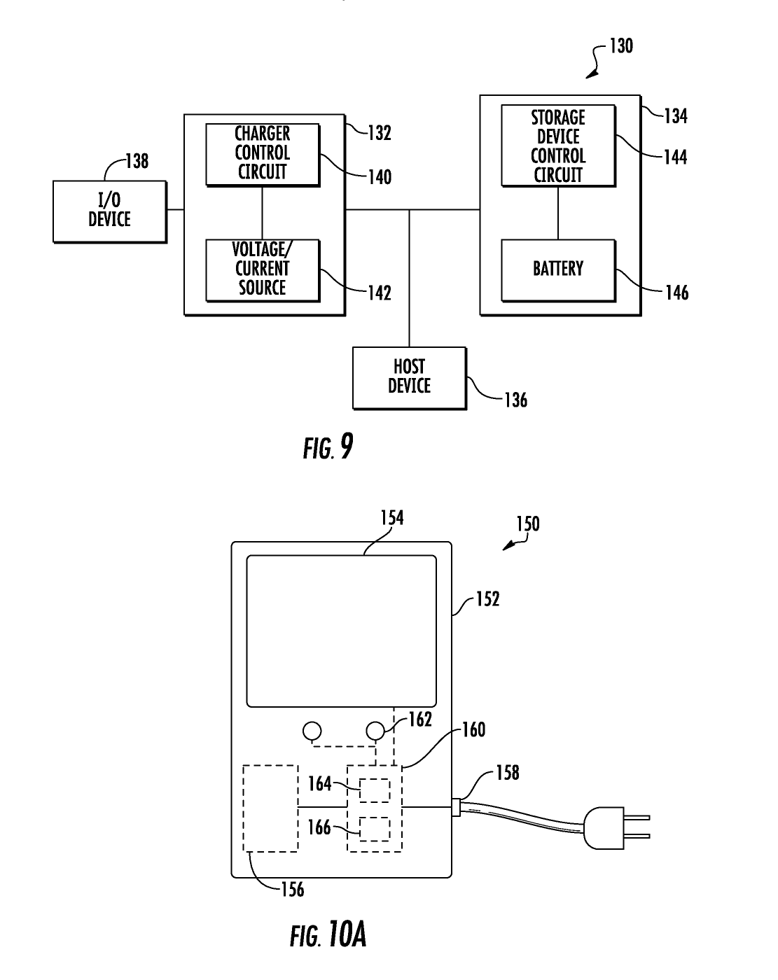

In some embodiments, charger 10 is configured to store charge or usage data (e.g., charge/discharge data) for one or more storage devices. For example, referring to FIG. 4, a graph 56 shows charge data for a rechargeable battery in terms of SOC 58 over time 60. Line 62 illustrates the SOC for the battery overtime, including various charge cycles 64 and discharge cycles 66. The charge data can be stored in charger 10, host device 30, or in a memory coupled to the battery (e.g., as part of a “smart battery” as shown in FIG. 8). The charge data can then be used to determine a current SOC, charging tolerance characteristics (e.g., values for charging current, voltage, and temperature that will not substantially adversely impact the battery), and the overall battery life. Referring to FIG. 4B, lines 63, 65, 67 represent capacity as a function of time for various charge rates. For example, in one embodiment, line 63 represents a fast charge, line 65 represents a medium-pace charge, and line 67 represents a slow charge. Lines 63, 65, 67 are provided for illustration purposes only, and the particular slope, shape, etc., may vary according to various alternative embodiments.

Charger 10 and circuit 34 can also be configured to take various dynamic impedance measurements at various current/voltage amplitudes and frequencies to determine tolerable current, voltage, and temperature levels during a charge cycle for a storage device. For example, impedance measurements can be cross-referenced to various battery models to determine appropriate charging parameters (e.g., current, voltage, temperature). As such, memory 38 can be configured to store battery modeling data for use in determining charge parameters for various batteries or other storage devices. Other factors that may be taken into account by circuit 34 include ambient temperature conditions, cooling conditions (e.g., air flow or other motion), current temperatures of a battery or battery cell, or cell-specific impendence or SOC levels. Any combination of these factors may be utilized as inputs during charging.

According to one embodiment, charger 10 is configured to provide a user with a variety of charging options for recharging a particular storage device such as a battery. For example, charging options can include a slow charge option (e.g., a regular, or optimal charge option), where the charge cycle is configured to fully charge a battery in the least amount of time while not significantly impacting the overall life of the battery. Charging options can also include fast charge options, such that elevated current, voltage, or temperature may be allowed in charging the battery in a shorter amount of time than in a slow charge. For each charge option, charger 10 can provide the user with an indication of the remaining storage device life, or alternatively, the impact on storage device life, resulting from the charging option.

For example, in some embodiments, charger 10 can provide users with a predicted remaining battery life for a battery for each charging option. The predicted remaining battery life can be expressed as charge cycles remaining, or time remaining (e.g., days, weeks, etc.) based on expected future use of a device (which can be predicted based on historic usage data for the device). As discussed in greater detail below, charger 10 can provide a number of fast charge options having different charge times and different battery life predictions, so as to enable a user to select a desired charging option.

In some embodiments, charging options can be customized by a user. For example, a user can provide one or more inputs to charger 10 (e.g., via display 14, buttons 16, or audio input/output device 18) regarding the charging of a battery or other device. In one embodiment, a user can specify a desired maximum charge time (i.e., specifying a maximum amount of time for a charge cycle). This may be useful when a user knows how much time the user has available for charging (e.g., time between airplane flights, time before or between meetings, etc.). In another embodiment, a user can specify a desired use time for the battery (i.e., specifying an amount of time the user expects to need to use a host device). This may be useful, for example, when a user knows how much time the user expects to use a host device. For example, the user may know the length of a flight is two hours, and specify that at least two hours of use time are desired.

In further embodiments, combinations of a charge time and a use time can be utilized. For example, if a user has one hour of use time remaining prior to boarding an aircraft for a three hour flight, the user can provide inputs indicating a desired maximum charge time of one hour and a desired minimum use time of three hours (e.g., in order to get the maximum charge prior to the flight). In yet further embodiments, the user can provide battery life impact inputs indicating a desired impact on the overall battery life. For example, the user may wish to know the maximum use time that can be obtained in two hours without impacting battery life. In such a case, the user can specify a two hour use time and no impact on overall battery life. Other inputs and combinations of inputs can be utilized according to various other embodiments. Any combination of inputs can be used by a user, and the charger can monitor battery characteristics during charging and dynamically change one or more charging parameters during the charge cycle to ensure the specified limitations on impact to the storage device are not exceeded.

Based on the various inputs received from the user, circuit 34 can determine various charging options for the user and display the options to the user via display device 14 or another output device. The user can then, based on knowing the various charging scenarios and associated impacts on the overall battery life, make an informed selection of one of the options. Charger 10 can then charge the battery in accordance with the selected option. Furthermore, circuit 34 can monitor various parameters during charging (e.g., an actual charge time, temperature of various components, etc.), and determine updated values for parameters such as charge time, use time, and battery life. In other words, circuit 34 can update the predicted values provided to the user prior to charging to determine, e.g., a more accurate value for the impact to battery life, etc. This data can be stored to be usable for future charging cycle use.

Referring now to FIG. 5, display 68 (e.g., user interface) of a plurality of charging options is shown according to one embodiment. Display 68 can be provided by display device 14 of charger 10, or alternatively, by a display of a host device such as device 30, or by another device. As shown in FIG. 5, display 68 provides a plurality of charging options 70 for charging a storage device. For each option, display 68 provides a charge time 72, a use time 74, and a storage device life 76. As discussed above, charge time 72 represents the time during which the storage device is charged, use time 74 represents the expected or predicted use time that will be available for using a particular host device after charging, and storage device life 76 represents the expected or predicted storage device life that will result from the charging option.

Referring further to FIG. 5, display 68 shows options 78 (option 1), 80 (option 2), 82 (option 3), and 84 (option 4), having decreasing charge times, decreasing use times, and decreasing battery life values. In one embodiment, one of the options (e.g., option 78) can be a conventional slow charge, and may be distinguished from the other options on display 68 by way of a visual indication that may include a different font, a different background color, textual indicators, etc. While FIG. 5 shows use time and storage device life decreasing with decreasing charge time (i.e., with faster charge rates), in other embodiments, use time and storage device life can vary in different ways with respect to various charge times.

Based on the displayed charging options, a user can select a desired charging option. In one embodiment, a selection can be made via a touchscreen device, such that a user can tap on a display screen in the area of the desired option. In other embodiments, a user can depress a button, provide a voice input, or provide another suitable type of input indicative of a desired charging option. Upon receiving the input from the user, charger 10 can proceed with charging the storage device in accordance with the selected charging option.

Referring now to FIG. 6, display 86 (e.g., user interface) showing a plurality of charging options is shown according to one embodiment. Display 86 can be provided by display device 12 of charger 10, or alternatively, by a display of a host device such as host device 30, or by another device. As shown in FIG. 6, display 86 can provide input areas 90, 92 configured to enable a user to enter desired values for a desired charge time (see, e.g., input area 90) or a desired use time (see, e.g., input area 92). Display 86 can also provide an indication of the remaining use time 88 for a storage device, such that the user can make an informed decision regarding various charging options. As shown in FIG. 6, display 86 provides a plurality of charging options 94 for charging a storage device to a user. For each option, display 86 provides a charge time 96, a use time 98, and a storage device life 100. As discussed above, charge time 96 represents the time during which the storage device is charged, use time 98 represents the expected or predicted use time that will be available for a particular host device after charging, and storage device life 100 represents the expected or predicted storage device life that will result from the charging option.

Referring further to FIG. 5, display 68 shows options 102 (option 1), 104 (option 2), and 106 (option 3), which may have differing values corresponding to different charging options. In one embodiment, a user can input a desired charge time and/or a desired use time using, for example, input areas 90, 92. Based on the inputs, circuit 34 can provide charging options that satisfy, or most closely satisfy, the inputs. In some embodiments, a user can leave one or both of the input areas blank, and circuit 34 can determine various charging options based on preset algorithms that provide, for example, maximum use time, minimum impact on storage device life, and so on.

Based on the displayed charging options, a user can select a desired charging option. In one embodiment, a selection can be made via a touchscreen device, such that a user can tap on a display screen in the area of the desired option. In other embodiments, a user can depress a button, provide a voice input, or provide another suitable type of input indicative of a desired charging option. Upon receiving the input from the user, circuit 34 can proceed with charging the storage device in accordance with the selected charging option.

Referring to FIG. 7, display 108 (e.g., user interface) showing different charging parameters for a charging cycle is shown according to one embodiment. Display 108 can be provided by display device 12 of charger 10, or alternatively, by a display of a host device such as host device 30, or by another device. As shown in FIG. 7, display 108 can provide values for charge time 110, required use time 112, and storage device life 114. Values for the parameters can be shown by indicators 116, 118, 120, which are shown in FIG. 7 to be bar indicators for charge time (indicator 116), use time (indicator 118), and storage device life (indicator 120).

Display 108 is configured to provide a user an indication of how a change in the value of one parameter can affect the values of one or more other parameters. In one embodiment, a user can provide an input to increase or decrease a parameter value. In response, circuit 34 determines the resultant changes to the other parameters and updates the display accordingly. In some embodiments, a user can indicate that they wish to hold the value of one of the parameters constant, such that when using three parameters, a change in the value of one parameter will result in a change in value for only one of the other parameters (the third being held constant).

In some embodiments, display 108 can implemented on a touchscreen display, such that to adjust the value of a parameter, the user can touch the appropriate bar indicator on the display and drag the end of the indicator to the desired level. Based on the change in one parameter, charger 10 can update display 108 and the appropriate indicators to reflect the corresponding change parameters. For example, should a user presented with display 108 wish to decrease the charge time, the user could drag bar indicator 116 to the left as shown in FIG. 7 to a desired level. In response, charger 10 may determine the use time will likewise be reduced, and move bar indicator 118 to the left. In some embodiments, charger 10 can be configured such that should a user attempt to drag a bar indicator beyond possible limits (e.g., beyond the maximum possible use time for a battery), the user will be provided with a notification (e.g., in the form of a visual notification, audible notification, etc.). In some embodiments, bar indicator 118 can show both an existing or current use time 122 and an additional use time 124 (resulting from the charge cycle). It should be noted that other types of indicators than those shown in FIG. 7 can be used according to various alternative embodiments. For example, an alternative limit may be the available charging power (e.g., in the case of electric car batteries and similar applications).

Referring now to FIG. 8, display 123 reflecting the results of a charging cycle is shown according to one embodiment. Display 123 is intended to provide a user with post-charge cycle indications of charge time 125, use time 127, and storage device life 129. Because post-charge cycle values can be based on the actual charge cycle, the indications may be more accurate than the predictions provided to the user prior to a charging cycle. As such, the user can see the actual impact of a chosen charging cycle. Differences between the expected or predicted values and the actual values can be based on a number of factors, including unexpected elevated temperatures, an unexpected stoppage of the charging cycle (resulting in a shortened charge time), or other factors. Additional data can be provided to users according to various alternative embodiments. For example, in some embodiments, suggestions (e.g., recommendation 131) can be provided to the user regarding future charging cycles (e.g., to restore a portion of battery life, etc.).

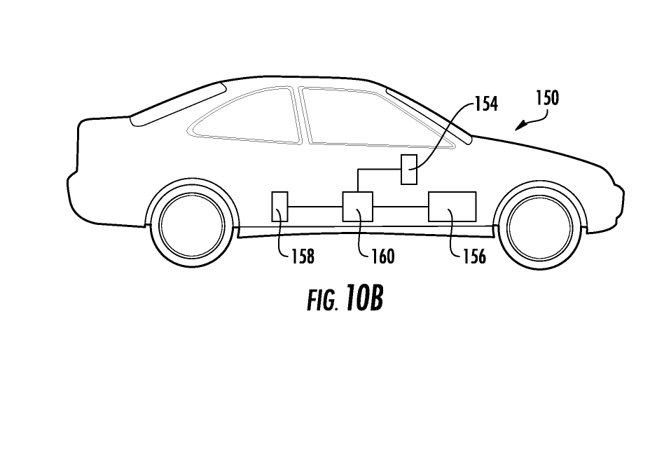

Referring back to FIGS. 1-2, charger 10 is shown as a separate component relative to storage device 32 and host device 30. According to various alternative embodiments, various components (e.g., controllers, memory, etc.) can be integrated into one or both of the storage device and host device to provide intelligent charging features. For example, referring to FIG. 9, a charging system 130 is shown according to one embodiment and includes charger 132 and battery assembly 134. Charger 132 can receive inputs from an input/output device 138, and can communicate with battery assembly 134 and a host device 136. Charger 132 includes a charger control circuit 140 and a current/voltage source 142. Battery assembly 134 includes battery 146 and battery control circuit 144. In alternative embodiments, battery 146 may be in the form of other energy storage devices, including any of those disclosed herein.

In one embodiment, battery control circuit 144 is configured to monitor usage of battery 146 (e.g., charge/discharge cycles, etc.) such that battery data associated with the usage history of battery 146 can be communicated to charger control circuit 140. Providing battery data to charger control circuit 140 may enable more accurate determinations to be made when providing users with charging options. Charger control circuit 140 can be configured to operate similar to circuit 34 of charger 10, and provide any of the displays and charging options to users as disclosed elsewhere herein (e.g., via an integrated display, via a host device display, etc.).

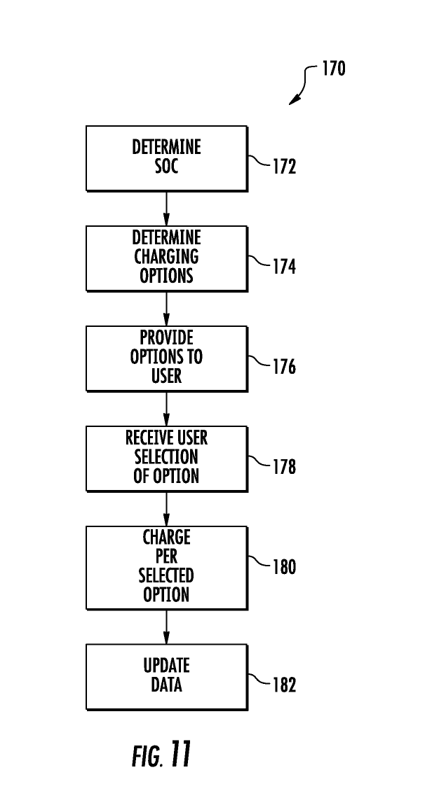

In a further embodiment, intelligent charging circuitry is integrated into a host device (e.g., a mobile device, vehicle, etc.). For example, referring to FIG. 10A, a host device 150 (e.g., an electronic device) is shown according to one embodiment as a mobile device, and includes housing 152, display 154, battery 156, and charging port 158. As with battery 146, battery 156 may take the form of any suitable energy storage device. Device 150 further includes circuit 160, which can control charging of battery of 156 and direct current/voltage from charging port 158 to battery 156. Circuit 160 includes processor 164 and memory 166, and can be configured to provide various displays to users (e.g., via display 154) and receive various inputs from users (e.g., via input devices 162, display 154, etc.). Device 150 can be configured to provide the same charging functionality as charger 10, such that various charging options and other data can be displayed to a user via display 154, and user inputs can be received via device 150, to provide various charging alternatives to users. As shown in FIG. 10B, in some embodiments, device 150 can be a vehicle (e.g., an electric vehicle, etc.) configured to be powered at least partially by electricity. As such, battery 156, charging port 158, circuit 160, and display 154 may be implemented within a vehicle. As noted elsewhere herein, in various further embodiments, battery 156 may take the form of other suitable energy storage devices.

Referring now to FIG. 11, method 170 of charging an energy storage device is shown according to one embodiment. A state of charge of the storage device is determined (172). As discussed above, the state of charge reflects the current state of the storage device, and can be determined in a variety of ways based on any of a number of factors. A plurality of charging options are determined (174) and provided to a user (176). The charging options can represent different charging scenarios, with each scenario having a different impact on storage device life. A user input is received indicating the option selected by the user (178), and the storage device is charged in accordance with the selected option (180). Various parameters (e.g., temperature, current/voltage levels, etc.) can be monitored during charging, such that after the charging cycle, storage device data can be updated (182). Updating the storage device data can include displaying various storage device information (e.g., use time, storage device life) to a user (see e.g., FIG. 8), and storing storage device data in a memory for use during future charging operations.

It should be noted that in some embodiments, charging options can be provided to a user without prompting the user for any desired charging information, such as a desired use time, a maximum charge time, etc. In other embodiments, the user can be prompted for various charging information, based upon which various charging options can be determined and presented to the user. Furthermore, in some embodiments, the state of charge of a storage device can be determined without any prior knowledge of the battery. In alternative embodiments, historic or other data regarding one or more storage devices can be stored in memory for use during charging operations.

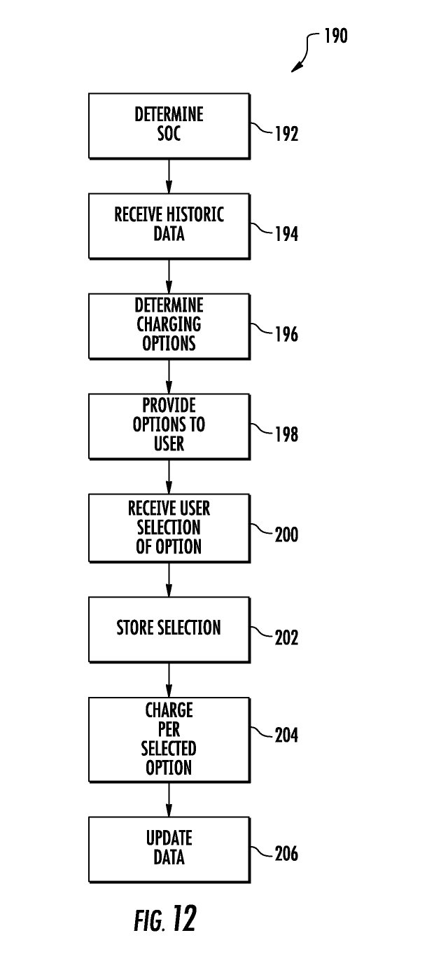

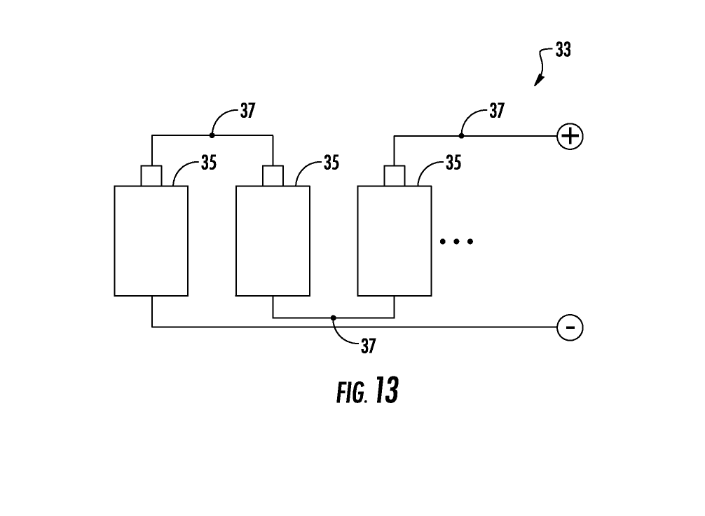

Referring now to FIG. 12, method 190 of charging an energy storage device is shown according to one embodiment. A state of charge of the storage device is determined (192). As discussed above, the state of charge reflects the current state of the storage device, and can be determined in a variety of ways based on any of a number of factors. Storage device data is received regarding the storage device (194). The storage device data can include operational characteristics (e.g., usage characteristics of how a storage device is being used, for example, in a cellular phone, electric car, etc.) of the storage device, historic usage data for the storage device, or other information. A plurality of charging options are determined (196) and provided to a user (198). The charging options can represent different charging scenarios, with each scenario having a different impact on storage device life. A user input is received indicating the option selected by the user (200), and the selection can be stored for future reference (202). In some embodiments, charging recommendations or options can be made based on past user charging selections. The storage device is charged in accordance with the selected option (204). Various parameters (e.g., temperature, current/voltage levels, etc.) can be monitored during charging, such that after the charging cycle, storage device data can be updated (206). Updating the storage device data can include displaying various storage device information (e.g., use time, storage device life) to a user, and storing storage device data in a memory for use during future charging operations.

The present disclosure contemplates methods, systems, and program products on any machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. When information is transferred or provided over a network or another communications connection (either hardwired, wireless, or a combination of hardwired or wireless) to a machine, the machine properly views the connection as a machine-readable medium. Thus, any such connection is properly termed a machine-readable medium. Combinations of the above are also included within the scope of machine-readable media. Machine-executable instructions include, for example, instructions and data which cause a general purpose computer, special purpose computer, or special purpose processing machines to perform a certain function or group of functions.

Although the figures may show a specific order of method steps, the order of the steps may differ from what is depicted. Also two or more steps may be performed concurrently or with partial concurrence. Such variation will depend on the software and hardware systems chosen and on designer choice. All such variations are within the scope of the disclosure. Likewise, software implementations could be accomplished with standard programming techniques with rule based logic and other logic to accomplish the various connection steps, processing steps, comparison steps and decision steps.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. An electronic device for use in charging an energy storage device, comprising:
a user interface device; and
a control circuit coupled to the user interface device and configured to:
determine a plurality of different options for charging an energy storage device, including determining a predicted impact on the overall life of the energy storage device for each of the plurality of options;
provide the plurality of options for charging the energy storage device to the user interface device, each of the plurality of options including an indication of the predicted impact on the overall life of the energy storage device;
receive a user input identifying a user selection of one of the plurality of options; and
charge the energy storage device in accordance with the selected option.

2. The device of claim 1, wherein the control circuit is configured to determine a current condition for the energy storage device and determine the plurality of options based at least in part on the current condition for the energy storage device.

3. The device of claim 2, wherein the current condition includes a state of charge of the energy storage device.

4. The device of claim 3, wherein the control circuit is configured to determine the state of charge for the energy storage device based on test measurements of the energy storage device.

5. The device of claim 4, wherein the test measurements include impedance measurements.

6. The device of claim 4, wherein the test measurements include voltage measurements.

7. The device of claim 4, wherein the test measurements include measurements regarding portions of a multi-cell battery.

8-9. (canceled)

10. The device of claim 1, wherein each of the plurality of options includes an expected charge time, an expected use time, and an indication of an expected impact on overall energy storage device life.

11-21. (canceled)

22. The device of claim 1, wherein the control circuit is configured to monitor charging characteristics including at least one of a charge cycle voltage, a charge cycle current, and a charge cycle temperature during charging of the energy storage device.

23. The device of claim 22, wherein the control circuit is configured to provide an updated value for at least one of charge time, use time, and energy storage device life to the user after charging the energy storage device.

24. The device of claim 23, wherein the control circuit is configured to determine the updated value based on the charging characteristics.

25-40. (canceled)

41. The device of claim 1, wherein the energy storage device is usable to power a laptop computer.

42. The device of claim 1, wherein the energy storage device is usable to power a vehicle.

43. An electronic device configured to charge an energy storage device, comprising:
an output device; and
a control circuit coupled to the output device, the control circuit configured to:
determine a plurality of options for charging an energy storage device, including determining a predicted impact on the overall life of the energy storage device for each of the plurality of options;
provide the plurality of options to a user via the output device; and
charge the energy storage device in accordance with one of the plurality of options.

44-51. (canceled)

52. The device of claim 43, wherein each of the plurality of options includes an expected charge time, an expected use time, and an indication of an expected impact on overall energy storage device life.

53. The device of claim 43, wherein the energy storage device is charged in accordance with a first user input, and wherein the control circuit is configured to determine the plurality of options based on a second user input associated with a charging parameter.

54. The device of claim 53, wherein the charging parameter includes a charge time.

55. The device of claim 54, wherein the charge time is a maximum charge time.

56. The device of claim 53, wherein the charging parameter includes a use time for the energy storage device.

57. The device of claim 56, wherein the use time is a minimum use time.

58. The device of claim 53, wherein the charging parameter includes an impact on energy storage device life.

59. The device of claim 58, wherein the impact on energy storage device life is a maximum impact on energy storage device life.

60-76. (canceled)

77. The device of claim 43, wherein the electronic device is a battery charger and includes a battery charging port configured to receive a battery.

78. The device of claim 43, wherein the electronic device is a host device configured to utilize power supplied by the energy storage device during a discharge cycle of the energy storage device.

79-84. (canceled)

85. A method of charging a battery, comprising:
determining a plurality of options for charging the battery;
predicting an impact on the overall life of the battery for each of the plurality of options;
providing the plurality of options for charging the battery to a user, each of the plurality of options including an indication of the predicted impact on the overall life of the battery;
receiving an input identifying one of the plurality of options; and
charging the battery in accordance with the selected option.

86-102. (canceled)

103. The method of claim 85, wherein one of the plurality of options is a slow charge option configured to minimize the impact on battery life.

104. The method of claim 85, wherein one of the plurality of options is a fast charge option configured to minimize the charge time required to provide a predetermined portion of a maximum charge capacity.

105. The method of claim 85, wherein at least two of the plurality of options are fast charge options having different impacts on overall battery life.

106. The method of claim 85, further comprising monitoring battery charging characteristics including at least one of a charge cycle voltage, a charge cycle current, and a charge cycle temperature during charging of the battery.

107. The method of claim 106, further comprising providing an updated value for at least one of charge time, use time, and battery life to the user after charging the battery.

108-110. (canceled)

111. The method of claim 85, further comprising storing the input and determining future charging options based on the input.

112. The method of claim 85, further comprising providing a suggestion to the user regarding future charge cycles.

113. The method of claim 112, wherein the suggestion is determined based on a future charging cycle predicted to restore a portion of the overall battery life.

114-121. (canceled)

122. The method of claim 85, wherein the input is received by a battery charger including a battery charging port configured to connect to the battery.

123. The method of claim 85, wherein input is received by a host device configured to utilize power supplied by the battery during a discharge cycle of the battery.

124-191. (canceled)
